(19) United States
(12) Patent Application Publication
(10) Pub. No.: US 2010/0144131 A1
(43) Pub. Date: Jun. 10, 2010

(54) METHOD FOR PRODUCING BONDED WAFER

(75) Inventor: Hidehiko Okuda, Tokyo (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: SUMCO CORPORATION, Tokyo (JP)

(21) Appl. No.: 12/630,604

(22) Filed: Dec. 3, 2009

(30) Foreign Application Priority Data
Dec. 4, 2008 (JP) 2008-309508

(51) Int. Cl. H01L 21/762

(52) U.S. Cl. 438/530; 257/E21.561

(57) ABSTRACT

A bonded wafer is produced by a step of forming an oxygen ion implanted layer, a step of forming a wafer composite, a step of exposing the oxygen ion implanted layer, and a step of obtaining an active layer, wherein the exposed oxygen ion implanted layer is removed by sequentially subjecting to a first HF treatment, a given oxidation heat treatment, and then a second HF treatment.

### BACKGROUND

1. Field of the Invention

This invention relates to a method for producing a bonded wafer, and more particularly to a method for producing a bonded wafer in which an oxygen ion implanted layer is provided on a wafer for active layer as a polishing and etching stop layer.

2. Description of the Related Art

The bonded wafer normally means a bonded SOI wafer. As the production method thereof are mentioned, for instance, a method wherein an oxidized wafer for active layer is bonded to a wafer for support substrate and thereafter a surface of the wafer for active layer is thinned to a given thickness by grinding and polishing as disclosed in a literature, “Science of Silicon”, edited by UCS Semiconductor Substrate Technology Workshop, published by REALIZE INC. on Jun. 28, 1996, pp 459-462, and an ion implantation-isolation method or a so-called smart cut (SMART CUT®) method comprising a step of forming an ion implanted layer by implanting ions of a light element such as hydrogen, helium or the like into a wafer for active layer at a given depth position, a step of bonding the wafer for active layer to a wafer for support substrate through an insulating film, a step of exfoliating at the ion implanted layer and a step of thinning a portion for active layer exposed at a state bonded to the wafer for support substrate by exfoliation to form an active layer of a given thickness as disclosed in WO 2005/074033.

In such a silicon wafer, it is assumed that it is important to make the thickness of the active layer thin and enhance the thickness uniformity thereof. To this end, the inventors have also disclosed the production technique of a bonded wafer satisfying the requirements for the thinning and the thickness uniformity of the active layer in WO 2005/074033. This technique is a production method characterized by comprising a time-series combination of a step of implanting oxygen ions into a wafer for active layer to form an oxygen ion implanted layer in the wafer for active layer, a step of subjecting the wafer for active layer to a heat treatment in a non-oxidizing atmosphere at a temperature of not lower than 1100° C., a step of bonding the wafer for active layer to a wafer for support substrate, a step of conducting a heat treatment for improving a bonded strength, a step of grinding a portion of the wafer for active layer in the bonded wafer short of the oxygen ion implanted layer, a step of further polishing or etching the wafer for active layer to expose the oxygen ion implanted layer, a step of subjecting the bonded wafer to an oxidation heat treatment to form an oxide film on the exposed surface of the oxygen ion implanted layer, a step of removing the oxide film, and a step of conducting a heat treatment in a non-oxidizing atmosphere at a temperature of not higher than 1100° C., wherein the oxygen ion implanted layer serves as a polishing and etching stop layer, and hence an active layer having a high thickness uniformity can be obtained without being etched.

In the production method disclosed in WO 2005/074033, however, although a certain effect is obtained on the ensuring of the thickness uniformity in the active layer through polishing and etching, since the oxygen ion implanted layer is a mixed layer of SiO₂ and Si, there is a fear that the oxygen ion implanted layer is excessively oxidized at the step of forming the oxide film on the exposed face of the oxygen ion implanted layer and hence the thickness uniformity of the active layer will be deteriorated after the oxidized oxygen ion implanted layer is removed by using HF (hydrofluoric acid) or the like (the step of removing the oxide film in WO 2005/074033). Since the deterioration of the thickness uniformity in the active layer has a bad influence on electric characteristics of a transistor, it is desired to improve such a deterioration, and further it is also desired to shorten the time required for removing the oxygen ion implanted layer.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

It is, therefore, an object of the invention to provide a method for producing a bonded wafer in which an oxygen ion implanted layer as a polishing and etching stop layer can be removed in a short time to ensure an excellent thickness uniformity of an active layer.

The inventors have made investigations for solving the above problems and focused attention on the fact that the oxygen ion implanted layer is a mixed layer of SiO₂ and Si and is difficult to be uniformly heat-treated at the oxidation heat treatment step by the conventional method. As a result of further studies, it has been found that the exposed oxygen ion implanted layer is subjected to an HF treatment (first HF treatment) prior to the conventional oxidation heat treatment and HF treatment in the step of removing the exposed oxygen ion implanted layer, whereby SiO₂ portion in the oxygen ion implanted layer is preferentially removed to form an oxygen ion implanted layer of a porous shape and as a result, the oxygen ion implanted layer can be removed in a shorter time by the subsequent oxidation heat treatment and HF treatment (second HF treatment) but also the oxygen ion implanted layer is not excessively oxidized nor removed, and hence there is obtained a bonded wafer capable of ensuring the excellent thickness uniformity of an active layer.

The invention is based on the above knowledge and the summary thereof is as follows.

(1) A method for producing a bonded wafer, comprising a step of implanting oxygen ions from a surface of a wafer for active layer to form an oxygen ion implanted layer at a given position inside the wafer for active layer, a step of bonding the wafer for active layer to a wafer for support substrate directly or through an insulating layer to form a wafer composite, a step of removing a portion of the wafer for active layer in the wafer composite by a given method to expose the oxygen ion implanted layer and a step of removing the exposed oxygen ion implanted layer to obtain an active layer of a given thickness, wherein the step of removing the exposed oxygen ion implanted layer is conducted by sequentially subjecting the exposed oxygen ion implanted layer to a first HF treatment, a given oxidation heat treatment, and then a second HF treatment.

(2) A method for producing a bonded wafer according to the item (1), wherein a concentration of HF used in the first HF treatment is within a range of 1 to 50 mass % and a treating time is not more than 60 minutes.

(3) A method for producing a bonded wafer according to the item (1), wherein in the oxidation heat treatment, a treating temperature is within a range of 700 to 1000° C. and a treating time is not more than 60 minutes.

According to the invention, it is possible to provide a method of producing a bonded wafer capable of removing an oxide ion implanted layer as a stop layer in a short time to ensure an excellent thickness uniformity of an active layer as well as a bonded wafer having a high thickness uniformity of an active layer produced by the production method.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 is a flow chart illustrating production steps for a bonded wafer according to the invention; and

FIG. 2 is a view illustrating the first HF treatment according to the invention, wherein (a) shows a state of a wafer composite before the first HF treatment and (b) shows a state of a wafer composite after the first HF treatment.

### DETAILED DESCRIPTION

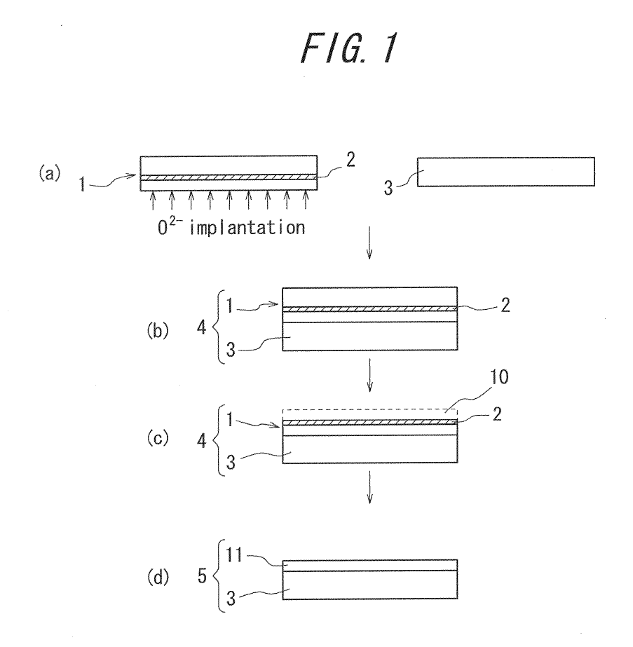

The method for producing a bonded wafer according to the invention will be described with reference to the drawings. FIG. 1 is a flow chart illustrating production steps for a bonded wafer according to the invention.

The production method of the bonded wafer according to the invention comprises a step of implanting oxygen ions from a surface of a wafer for active layer 1 to form an oxygen ion implanted layer 2 at a given position inside the wafer for active layer 1 (FIG. 1(a)); a step of bonding the wafer for active layer 1 to a wafer for support substrate 3 directly or through an insulating layer to form a wafer composite 4 (FIG. 1(b)); a step of removing a portion 10 of the wafer for active layer 1 in the wafer composite 4 by a given method to expose the oxygen ion implanted layer 2 (FIG. 1(c)); and a step of removing the exposed oxygen ion implanted layer 2 to obtain an active layer 11 of a given thickness (FIG. 1(d)).

In FIGS. 1(a) to (d), for convenience, the presence of the oxygen ion implanted layer 2 is clearly shown at an exaggeratedly thickened state in the wafer for active layer 1 so as to locate close to a central portion of the wafer for active layer 1 and further the presence of the active layer 11 is clearly shown at an exaggeratedly thickened state, but the oxygen ion implanted layer 2 and the active layer 11 are actually existent as thinly as not shown in the vicinity of a bonding interface between the wafer for active layer 1 and the wafer for support substrate 3.

(Step of Forming Oxygen Ion Implanted Layer)

The step of forming an oxygen ion implanted layer according to the invention (FIG. 1(a)) is a step of implanting oxygen ions from the surface of the wafer for active layer 1 to form the oxygen ion implanted layer 2 at a given position inside the wafer for active layer 1. The oxygen ion implanted layer 2 serves as a stop layer in the subsequent step of thinning the wafer for active layer 1 (FIG. 1(c)).

The position of forming the oxygen ion implanted layer in the wafer for active layer 1 as well as an acceleration voltage and a dose of the oxygen ion implantation accompanied therewith are not particularly limited, and may be properly selected depending on a target thickness of the active layer 11. Preferably, the acceleration voltage is within a range of 100 to 300 keV and the oxygen dose is within a range of 5.0×10¹⁶ to 5.0×10¹⁷ atoms/cm².

Moreover, the oxygen ion implanted layer 2 is preferable to have an oxygen concentration peak of not less than 1.0×10²² atoms/cm³. Although oxygen ions in the oxygen ion implanted layer react with Si in the wafer for active layer 1 at the subsequent heat-treating step (not shown) to form SiO₂ particles, if the oxygen concentration peak is less than 1.0×10²² atoms/cm³, the number of SiO₂ particles is small and a distance between the SiO₂ particles becomes wider to cause a gap, and hence there are generated places not serving as a stop layer for polishing and etching.

Furthermore, after oxygen ions are implanted in the surface of the wafer for active layer 1 to form the oxygen ion implanted layer 2 in the oxygen ion implantation step, it is preferable to conduct a heat treatment at a temperature of not lower than 1100° C. in a non-oxidizing atmosphere of hydrogen, argon or the like. By this heat treatment is rendered the form of the oxygen ion implanted layer 2 into a relatively continuous state, which can enhance the function as stop layer for polishing and etching.

When the heat-treating temperature is lower than 1100° C., the oxygen ion implanted layer having a sufficient continuity is not formed, and there is a tendency that only the result similar to the case not conducting the heat treatment is obtained, so that the heat-treating temperature is set to not lower than 1100° C. Moreover, the upper limit of the heat-treating temperature is not particularly limited, but is preferable to be not higher than 1250° C. from the viewpoint of the risk of causing slip dislocation.

(Step of Forming Wafer Composite)

The step of forming a wafer composite according to the invention (FIG. 1(b)) is a step of bonding the wafer for active layer 1 to the wafer for support substrate 3 directly or through an insulating layer. The wafer composite 4 according to the invention is assumed to be in both a case of bonding wafers through the insulating layer and a case of bonding the wafers directly without the insulating layer, so that the bonding method and conditions are not limited, and the bonding may be conducted by a method and conditions typically used.

After the bonding step (FIG. 1(b)), the wafer composite 4 may be subjected to a heat treatment step (not shown) for increasing the bonding strength if necessary. In this heat treatment step, an atmosphere gas is not particularly limited, while it is preferable to conduct the heat treatment at a treating temperature of 1100° C. for a treating time of about not less than 60 minutes. When the temperature is lower than 1100° C., the reaction at the bonding interface is hardly promoted and hence it is feared that a sufficient bonding strength is not obtained. Similarly, when the time is less than 60 minutes, it is feared that a sufficient bonding strength is not obtained. The upper limit of the treating temperature may be about 1350° C. not melting silicon, which increases a risk of causing slip dislocation, so that it is more preferable to be about 1100 to 1200° C.

(Step of Exposing Oxygen Ion Implanted Layer)

The step of exposing the oxygen ion implanted layer according to the invention (FIG. 1(c)) is a step of thinning a portion 10 of the wafer for active layer 1 in the wafer composite 4 by a given method and removing it to expose the oxygen ion implanted layer 2.

The thinning of the portion 10 of the wafer for active layer 1 is a step of removing the portion 10 of the wafer for active layer 1 in the wafer composite 4 to a given position not exposing the oxygen ion implanted layer 2 by a given method.

The method of thinning the portion 10 of the wafer for active layer 1 is not particularly limited, and may be, for example, the removal by grinding or the removal by exfoliation through the ion implantation-isolation method. The given position not exposing the oxygen ion implanted layer 2 is not particularly limited as long as it is a position before the oxygen ion implanted layer 2 is exposed, but it is preferable to be about 5 to 15 μm above the oxygen ion implanted layer 2. When the position exceeds 15 μm, the portion 10 of the wafer for active layer 1 becomes too thick and the time required for exposing the active layer by the subsequent etching is long, while when it is less than 5 μm, there is a fear that the oxygen ion implanted layer 2 may be exposed by an error of the grinding or the like.

After the thinning of the portion 10 of the wafer for active layer 1 as mentioned above, the oxygen ion implanted layer 2 is exposed by polishing (FIG. 1(c)). The polishing method is not limited, and the polishing can be conducted, for example, by using a typical polishing apparatus while supplying a polishing agent containing silica. Also, the kind of the polishing agent is not limited, and an alkaline solution having an abrasive concentration of not more than 1 mass % (such as the one containing amine as a major component) can be used, for example. By the chemical polishing action of the alkaline solution can be removed only the remaining portion 10 in the wafer for active layer 1 because the alkaline solution has a large difference in an etching rate between Si and SiO₂ and hardly polishes the oxygen ion implanted layer 2.

Also, the oxygen ion implanted layer 2 may be exposed by an etching instead of the polishing. The etching conditions are not particularly limited as long as they can efficiently remove the portion 10 of the wafer for active layer 1. For example, the etching can be conducted by immersing the wafer composite 4 after the thinning into an etching solution having a large difference in the etching rate between Si and SiO₂ (an alkaline etching solution dissolving KOH or the like).

(Step of Removing Oxygen Ion Implanted Layer)

The step of removing the oxygen ion implanted layer according to the invention (FIG. 1(d)) is a step of removing the exposed oxygen ion implanted layer 2 to obtain an active layer 11 of a given thickness. The step of removing the oxygen ion implanted layer 2 is characterized by sequentially subjecting the exposed oxygen ion implanted layer 2 to a first HF treatment, a given oxidation heat treatment, and then a second HF treatment. This is for removing the oxygen ion implanted layer 2 in a short time to ensure an excellent thickness uniformity of the active layer 11.

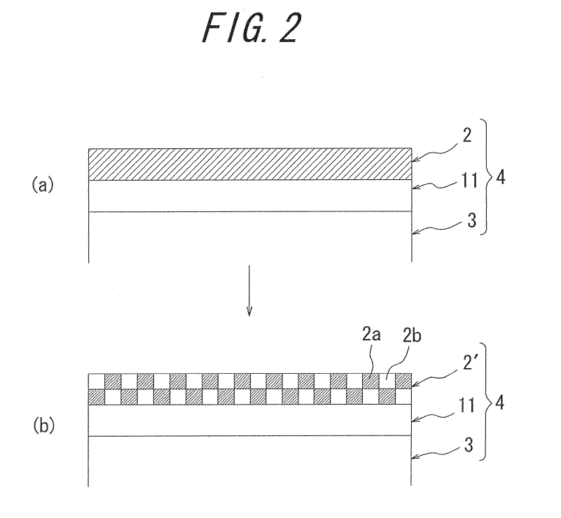

FIG. 2 is a flow chart illustrating the first HF treatment in the step of removing the oxygen ion implanted layer according to the invention (FIG. 1(d)), wherein (a) and (b) show states of the wafer composite 4 before and after the first HF treatment, respectively. As shown in FIGS. 2(a) and (b), it is clear that by subjecting the exposed oxygen ion implanted layer 2 to an HF treatment (first HF treatment) as a pre-stage of the oxidation heat treatment is formed an oxygen ion implanted layer 2′ of a porous shape removing a part of the oxygen ion implanted layer. Concretely, it is considered that since the oxygen ion implanted layer 2 is a mixed layer of Si and SiO₂, an HF solution used in the first HF treatment preferentially removes SiO₂, owing to its difference of etching rate, to form the porous oxygen ion implanted layer 2′ retaining mainly Si element.

Thereafter, by subjecting the porous oxygen ion implanted layer 2′ to the oxidation heat treatment and the second HF treatment, it is made possible to efficiently oxidize the whole of the oxygen ion implanted layer 2′ and remove it in a short time by the second HF treatment as compared with the conventional production method, so that an excellent thickness uniformity of the active layer 11 can be ensured in a short treating time.

Moreover, the first and second HF treatments concretely are treatments of immersing the oxygen ion implanted layers 2 and 2′ in a given HF solution. In the first HF treatment, it is preferable that a concentration of HF solution is within a range of 1 to 50 mass % and the treating time is within 60 minutes. When the concentration of the HF solution is less than 1 mass %, the effect of making the ion implanted layer 2 to the porous shape is not obtained, while when the concentration exceeds 50 mass %, it is feared that the HF solution penetrates into the active layer to cause rough surface of the active layer. Typically, an HF solution having a concentration of about 10 to 20 mass % is used. The reason why the first HF treating time is within 60 minutes is due to the fact that when it exceeds 60 minutes, there is a fear of causing the rough surface of the active layer but also since the first HF treatment is a treatment not conducted in the conventional production method, as the treating time becomes longer, the production time is prolonged resulting in a steep rise of the production cost.

The oxidation heat treatment is a treatment of thermally oxidizing the oxygen ion implanted layer 2′, which can selectively remove the oxygen ion implanted layer since the etching rate of HF solution against SiO₂ is larger than that against Si. In the invention, since the porous oxygen ion implanted layer 2′ having many voids is formed by the above first HF treatment, it is possible to shorten the time of the oxidation heat treatment, which conventionally requires about 4 hours. Further, the oxidation heat treatment is preferable to be a treating temperature within a range of 700 to 1000° C. and a treating time within 60 minutes. When the treating temperature is lower than 700° C., there is a fear that the oxygen ion implanted layer 2′ can not be oxidized sufficiently, while when it exceeds 1000° C., there is a fear that defects or dislocations existing in the oxygen ion implanted layer 2′ and the vicinity thereof grow. Moreover, when the treating time exceeds 60 minutes, there is a fear of deteriorating the thickness uniformity of the active layer due to excessive oxidization. From a viewpoint that the treatment in a short time is one characteristic of the invention, the treating time is more preferable to be within 15 minutes.

As a result, the bonded wafer 5 in which the thickness uniformity of the active layer 11 is within a range of 5 to 10% can be obtained by the production method according to the invention (FIGS. 1 (a) to (d)). Since the conventional production method deteriorates the thickness uniformity of active layer to about 20%, typically, the production method according to the invention substantially improves the thickness uniformity. The thickness uniformity (%) in the invention can be obtained, for example, by measuring the thickness of the active layer at any 121 places by means of a spectroscopic ellipsometer and calculating variation from an average value of the measured thicknesses, but the method is not limited as long as it can evaluate thickness uniformity.

Although the above is described with respect to only one embodiment of the invention, various modifications may be made without departing from the scope of the appended claims.

### Example 1

As shown in FIG. 1, there are provided two P-type (100) silicon wafers of 300 mm in diameter, one of which is used as a silicon wafer for active layer 1 and oxygen ions are implanted from a surface thereof twice under conditions that an acceleration voltage is 200 keV, a temperature is 200 to 600° C. and a dose is 3.0×10¹⁷ atoms/cm² and that an acceleration voltage is 200 keV, a temperature is not higher than 300° C. and a dose is 5.0×10¹⁵ atoms/cm². As a result, an oxygen ion implanted layer 2 is formed at a depth position of about 400 nm from the surface of the wafer for active layer 1 (FIG. 1(a)). Then, the wafer for active layer 1 and a wafer for support substrate 3 are cleaned with HF ozone solution to remove particles on the bonding faces of both wafers and thereafter directly bonded to form a wafer composite 4 (FIG. 1(b)). Then, in order to strongly bond the bonding surfaces, the wafer composite is subjected to a heat treatment in an oxidized gas atmosphere at 1100° C. for 2 hours (not shown).

Next, a portion 10 of the wafer for active layer 1 is thinned with a grinding apparatus and polished with a single-sided minor-polishing apparatus to expose the entire face of the oxygen ion implanted layer 2 (FIG. 1(c)).

Thereafter, the exposed oxygen ion implanted layer 2 is rendered into a porous oxygen ion implanted layer 2′ by immersing in a 10 mass % HF solution for 20 minutes (first HF treatment), and the removal of the oxygen ion implanted layer 2 is carried out by sequentially conducting an oxidation heat treatment (at 850° C. for 15 minutes) and a treatment of immersing the oxygen ion implanted layer 2′ in a 10 mass % HF solution for 10 minutes (second HF treatment) to thereby obtain a bonded wafer 5 as a sample (FIG. 1(d)).

### Example 2

A sample bonded wafer is obtained by the same steps as in Example 1 except that the condition of the first HF treatment is immersion in a 1 mass % HF solution for 20 minutes.

### Example 3

A sample bonded wafer is obtained by the same steps as in Example 1 except that the condition of the first HF treatment is immersion in a 1 mass % HF solution for 60 minutes.

### Example 4

A sample bonded wafer is obtained by the same steps as in Example 1 except that conditions of the first HF treatment is immersion in a 50 mass % HF solution for 20 minutes.

### Comparative Example 1

A sample bonded wafer is obtained by the same steps as in Example 1 except that the wafer composite 4 is subjected to the oxidation heat treatment (at 850° C. for 15 minutes) and a treatment of immersing in a 10 mass % HF solution for 10 minutes (second HF solution) without conducting the first HF treatment.

### Comparative Example 2

A sample bonded wafer is obtained by the same steps as in Example 1 except that the wafer composite 4 is subjected to the oxidation heat treatment (at 850° C. for 120 minutes) and a treatment of immersing in a 10 mass % HF solution for 10 minutes (second HF solution) without conducting the first HF treatment.

### Comparative Example 3

A sample bonded wafer is produced by the same steps as in Example 1 except that the wafer composite 4 is subjected to the oxidation heat treatment (at 850° C. for 270 minutes) and a treatment of immersing in a 10 mass % HF solution for 10 minutes (second HF solution) without conducting the first HF treatment.

### Comparative Example 4

A sample bonded wafer is produced by the same steps as in Example 1 except that the wafer composite 4 is subjected to the oxidation heat treatment (at 850° C. for 540 minutes) and a treatment of immersing in a 10 mass % HF solution for 10 minutes (second HF solution) without conducting the first HF treatment.

(Evaluation Methods)

(1) Thickness Uniformity of Active Layer

Each sample obtained in Examples and Comparative Examples is thinned to a desired active layer thickness, and thereafter the thickness (nm) of an active layer is measured at 121 places by means of a spectroscopic ellipsometer to calculate an average, and then the variation at each measured place is calculated from the average thickness to obtain the thickness uniformity of the active layer. The results are shown in Table 1.

(2) Defect Density of Active Layer

Each sample obtained in Examples and Comparative Examples is immersed in a 50 mass % HF solution for 30 minutes, and thereafter the number of defects per 1 cm² is measured at any 10 places and the values measured at 10 places are averaged to obtain the defect density of the active layer (number/cm²). The results are shown in Table 1.

TABLE 1

| | First HF | | | | |
|---|---|---|---|---|---|
| | treating | | Second HF | | |
| | conditions | Oxidation heat | treatment | Thickness | |
| | (solution | treating | (solution | uniformity | |
| | concentration, | conditions | concentration, | of active | Defect |
| | immersion | (temperature, | immersion | layer | density |
| | time) | treating time) | time) | (%) | (number/cm²) |
| Example 1 | 10%, 20 min | 850° C., 15 min | 10%, 10 min | 8.5 | 0.15 |
| Example 2 | 1%, 20 min | 850 C.°, 15 min | | 12.0 | 0.20 |
| Example 3 | 1%, 60 min | 850 C.°, 120 min | | 9.2 | 0.18 |
| Example 4 | 50%, 20 min | 850 C.°, 270 min | | 9.5 | 0.21 |
| Comparative | — | 850 C.°, 15 min | | 16.5 | 0.25 |
| Example 1 | | | | | |
| Comparative | — | 850 C.°, 120 min | | 17.5 | 0.32 |
| Example 2 | | | | | |
| Comparative | — | 850 C.°, 270 min | | 27.0 | 0.28 |
| Example 3 | | | | | |
| Comparative | — | 850 C.°, 540 min | | 23.6 | 0.15 |
| Example 4 | | | | | |

As seen from the results of Table 1, Example 1 is excellent in both the thickness uniformity of the active layer and the defect density as compared to Comparative Examples 1 to 4. It is also found that the sufficient effect is obtained by the oxidation heat treatment of 15 minutes in Example 1.

According to the invention, it is possible to provide a method of producing a bonded wafer capable of removing an oxide ion implanted layer as a stop layer in a short time to ensure an excellent thickness uniformity of an active layer as well as a bonded wafer having a high thickness uniformity of an active layer produced by the production method.

While illustrative embodiments have been illustrated and described, it will be appreciated that various changes can be made therein without departing from the spirit and scope of the invention.

The embodiments of the invention in which an exclusive property or privilege is claimed are defined as follows:

1. A method for producing a bonded wafer, comprising
a step of implanting oxygen ions from a surface of a wafer for active layer to form an oxygen ion implanted layer at a given position inside the wafer for active layer,
a step of bonding the wafer for active layer to a wafer for support substrate directly or through an insulating layer to form a wafer composite,
a step of removing a portion of the wafer for active layer in the wafer composite by a given method to expose the oxygen ion implanted layer and
a step of removing the exposed oxygen ion implanted layer to obtain an active layer of a given thickness, wherein the step of removing the exposed oxygen ion implanted layer is conducted by sequentially subjecting the exposed oxygen ion implanted layer to a first hydrofluoric acid (HF) treatment, a given oxidation heat treatment, and then a second HF treatment.

2. A method for producing a bonded wafer according to claim 1, wherein a concentration of HF used in the first HF treatment is within a range of 1 to 50 mass % and a treating time is not more than 60 minutes.

3. A method for producing a bonded wafer according to claim 1, wherein in the oxidation heat treatment, a treating temperature is within a range of 700 to 1000° C. and a treating time is not more than 60 minutes.
